(19) United States
(12) Patent Application Publication
(10) Pub. No.: US 2010/0032005 A1
(43) Pub. Date: Feb. 11, 2010

(54) SYSTEM AND METHOD FOR SOLAR ENERGY CAPTURE

(76) Inventors: Joseph Ford, Solana Beach, CA (US); Jason Karp, La Jolla, CA (US)

Correspondence Address: WHYTE HIRSCHBOECK DUDEK S C;INTELLECTUAL PROPERTY DEPARTMENT, 555 EAST WELLS STREET, SUITE 1900, MILWAUKEE, WI, 53202, US

(21) Appl. No.: 12/537,951

(22) Filed: Aug. 7, 2009

Related U.S. Application Data
(60) Provisional application No. 61/088,069, filed on Aug. 12, 2008.
(60) Provisional application No. 61/087,447, filed on Aug. 8, 2008.

(51) Int. Cl. H01L 31/052

(52) U.S. Cl. 136/246

(57) ABSTRACT

A system and a method for capturing solar energy are disclosed herein. In at least one embodiment, the method includes receiving light at a plurality of lenses, communicating the light from respective ones of the plurality of lenses toward respective ones of a plurality of dichroic mirrors, and transmitting respective first portions of the light through the respective ones of the dichroic mirrors toward respective first photovoltaic cells. The method also includes reflecting respective second portions of the light off of the respective ones of the dichroic mirrors toward respective adjacent ones of the dichroic mirrors, where the first portions are within a first wavelength range and the second portions are within a second wavelength range, and reflecting the respective second portions of the light off of the respective adjacent ones of the dichroic mirrors toward respective second photovoltaic cells.

### CROSS-REFERENCE TO RELATED APPLICATIONS

This application claims the benefit of U.S. Provisional Patent Application No. 61/088,069, entitled “System and Method for Solar Energy Capture” filed on Aug. 12, 2008, which is incorporated herein by reference, and also claims priority to U.S. Provisional Application No. 61/087,447, entitled “System and Method for Solar Energy Capture” filed on Aug. 8, 2008, which is hereby incorporated by reference herein.

### FIELD OF THE INVENTION

The present invention relates to solar energy systems and methods and, more particularly, to systems and methods for capturing solar energy that operate at least in part by way of concentrating received light prior to conversion of the light into electrical or other power.

### BACKGROUND OF THE INVENTION

Solar energy systems are of greatly increased interest due to rising energy demands worldwide and consequent rising prices for existing energy resources, especially petroleum resources. While much effort is being focused upon developing more efficient photovoltaic (PV) cells that can generate greater amounts of electrical energy based upon a given amount of solar radiation directed upon those cells, high efficiency PV cells nevertheless remain expensive. A less-expensive alternative to employing high efficiency PV cells is to employ low (or lower) efficiency PV cells. However, such PV cells need to be implemented across larger surface areas in order to collect sufficient solar radiation so as to generate the same amount of energy as can developed using high efficiency PV cells having a smaller surface area.

Although the efficiency of a PV-based solar energy system depends upon the efficiency of the PV cell(s) employed in that system, the amount of energy generated by such a system can also be enhanced without increasing the efficiency of the PV cell(s) or employing larger area PV cell(s) by combining the use of PV cell(s) with additional devices that concentrate the solar radiation prior to directing it upon the PV cell(s). Because such solar concentration devices can employ components that are less expensive than the PV cell(s) themselves, a solar energy system employing such a solar concentration device in combination with PV cell(s) covering a relatively small surface area can potentially produce, at a lower cost, the same high level of energy output as that achieved by a solar energy system employing only PV cell(s) of the same or greater area. Also, a solar energy system employing such a solar concentration device in addition to high efficiency PV cell(s) covering a relatively small area can achieve higher levels of energy output than would be possible using those PV cell(s) alone, even if those cells covered a larger area.

While potentially providing such advantages, existing solar energy systems employing both PV cell(s) and solar concentration devices have certain disadvantages as well. Many PV cell(s) are particularly efficient for converting light within a particular range of wavelengths, but not others, due to material bandgaps. Consequently, many existing solar energy systems employing both PV cell(s) and solar concentrators employ designs that cause light within a first wavelength range to be directed toward PV cell(s) of one type while causing light within a second wavelength range to be directed toward PV cell(s) of a different type. Yet many prior art designs of this type having multiband concentrators employ PV cells on circuit boards that are adjacent and orthogonal. Typically, in such designs, light within the first wavelength range is allowed to pass through a mirror device so as to reach the PV cell(s) of the first type that are suitable for that light, while light within the second wavelength range is reflected off of the mirror device in a direction orthogonal to the direction of the incoming light, so as to reach the PV cell(s) of the second type that are suitable for that light. The use of such adjacent, orthogonal PV cells makes thermal management difficult, reduces the upward-facing fill-factor and also increases production costs.

Other forms of conventional non-imaging concentrators include the cone concentrator and the compound parabolic concentrator. Both of these make use of reflective (mirrored or total internal reflection (TIR)) surfaces to fold ray paths to a detector plane. Combining a refractive element along with these non-imaging concentrator designs can yield much larger acceptance angles. Executions using a lens paired with a cube beamsplitter provides the spectral division previously stated. However, for such designs, the PV cells still must be placed orthogonal to one another leading to problems in packaging and thermal management.

It would therefore be advantageous if an improved design for a solar energy system employing both PV cell(s) and solar concentration devices could be developed. More particularly, it would be advantageous if such an improved design allowed for light within different wavelength ranges to be directed toward PV cell(s) of different types that were suitable for the different wavelengths of light, while at the same time achieved this operation without suffering from one or more of the disadvantages associated with conventional designs.

### SUMMARY OF THE INVENTION

The present inventors have recognized the above disadvantages associated with conventional solar energy systems in which a solar concentrator directs photons of different wavelengths toward adjacent, orthogonal PV cells. The present inventors have further recognized that an improved solar concentrator could overcome the aforementioned difficulties if it employed pairs of mirror devices (for example, dichroic beamsplitters) that operated together to doubly reflect some of the incoming light before it was directed to the PV cells.

In at least one embodiment utilizing such pairs of mirror devices, incoming light is first separated into first and second light portions (corresponding to different wavelength ranges) at a first mirror device of each given pair, where that mirror device passes the first portion of the light towards first PV cell(s) suitable for receiving such light and also reflects the second portion of the light in a direction substantially orthogonal to the direction of the incoming light. Subsequently, at a second mirror device of the given pair, the reflected second portion of the light is reflected a second time so as to proceed in a direction substantially parallel to that of the original incoming light, towards second PV cell(s) that are suitable for receiving such light. By virtue of the second reflection, both the first and second PV cell(s) can be located adjacent to one another in a co-planar manner. In at least one such embodiment, the first mirror of each (or nearly each) given pair of mirror devices doubly serves as the second mirror for an adjacent (partly-overlapping) pair of the mirror devices.

In at least some such embodiments, a multiband solar concentrator simultaneously provides moderate (10×) aperture concentration and wavelength splitting. The mirror devices divide the incident spectrum into visible and near-infrared/infrared wavelengths that propagate into first PV cell(s) and second PV cell(s) that are respectively optimized for each spectral band. Individual light paths are incident on a common printed circuit board with interleaved PV cells for each spectral band. Reflective sidewalls resembling a cone concentrator aid in the confinement of light from wide angles as they are directed and concentrated onto each individual PV cell. Each element is designed for concatenation into an array. A large area solar cell can be constructed from many small cells located side by side in a 1D or 2D arrangement.

The present invention relates, in at least some embodiments, to a system for capturing solar energy. The system includes a plurality of lenses arranged side-by-side with respect to one another, each of which is capable of receiving and focusing a respective amount of sunlight, and a plurality of dichroic mirrors that respectively extend diagonally away from respective ones of the lenses, and that are positioned so that the respective amounts of sunlight focused by the respective lenses are respectively incident upon the respective dichroic mirrors. The system further includes a plurality of pairs of first and second photovoltaic cells arranged substantially side-by-side with one another along a substantially planar surface, where each of the dichroic mirrors is positioned substantially in between a respective one of the lenses and at least the first photovoltaic cell of a respective one of the pairs of photovoltaic cells. The first photovoltaic cell of each of the respective pairs receives a respective first portion of the respective amount of sunlight focused by the respective one of the lenses that is transmitted through the respective dichroic mirror, and the second photovoltaic cell of each of the respective pairs receives a respective second portion of the respective amount of sunlight focused by the respective one of the lenses that is reflected by the respective dichroic mirror and subsequently reflected again by a respective neighboring one of the plurality of dichroic mirrors prior to arriving at the respective second photovoltaic cell.

Additionally, in at least some embodiments, the present invention relates to a method for capturing solar energy. The method includes receiving light at a plurality of lenses, communicating the light from respective ones of the plurality of lenses toward respective ones of a plurality of dichroic mirrors, and transmitting respective first portions of the light through the respective ones of the dichroic mirrors toward respective first photovoltaic cells. The method also includes reflecting respective second portions of the light off of the respective ones of the dichroic mirrors toward respective adjacent ones of the dichroic mirrors, where the first portions are within a first wavelength range and the second portions are within a second wavelength range, and reflecting the respective second portions of the light off of the respective adjacent ones of the dichroic mirrors toward respective second photovoltaic cells, whereby the first and second portions of the light are converted into electrical power by way of the first and second photovoltaic cells, respectively.

Further, in at least some embodiments, the present invention relates to a method of capturing light energy. The method includes receiving a plurality of amounts of light at a plurality of dichroic mirrors, respectively. The method also includes transmitting respective first portions of the respective amounts of light through respective ones of the dichroic mirrors for receipt by a plurality of first photovoltaic cells, respectively. The method additionally includes doubly reflecting respective second portions of the respective amounts of light, first off of the respective ones of the dichroic mirrors and then additionally off of respective adjacent ones of the dichroic mirrors for receipt by a plurality of second photovoltaic cells, respectively, the first photovoltaic cells and the second photovoltaic cells being arranged in an alternating manner with respect to one another.

### BRIEF DESCRIPTION OF THE DRAWINGS

FIG. 1 is a schematic, perspective view of components of an exemplary solar energy device allowing for both concentration of incoming light as well as separation of such light into light portions within different wavelength ranges that are in turn directed to different types of PV cells, respectively, in accordance with at least one embodiment of the present invention;

FIG. 2A is a schematic, side view of an exemplary component that can be implemented in the solar energy device of FIG. 1 (or within a device similar thereto), and FIG. 2B is a cross-sectional view of that component taken along line B-B of FIG. 2A;

FIGS. 3A and 3B are schematic side and perspective views, respectively, of an assembly encompassing several of the components of FIGS. 2A-B; and

FIG. 3C is a schematic perspective view of several of the assemblies of FIGS. 3A and 3B mounted side-by-side to form a larger assembly.

### DETAILED DESCRIPTION OF THE PREFERRED EMBODIMENT

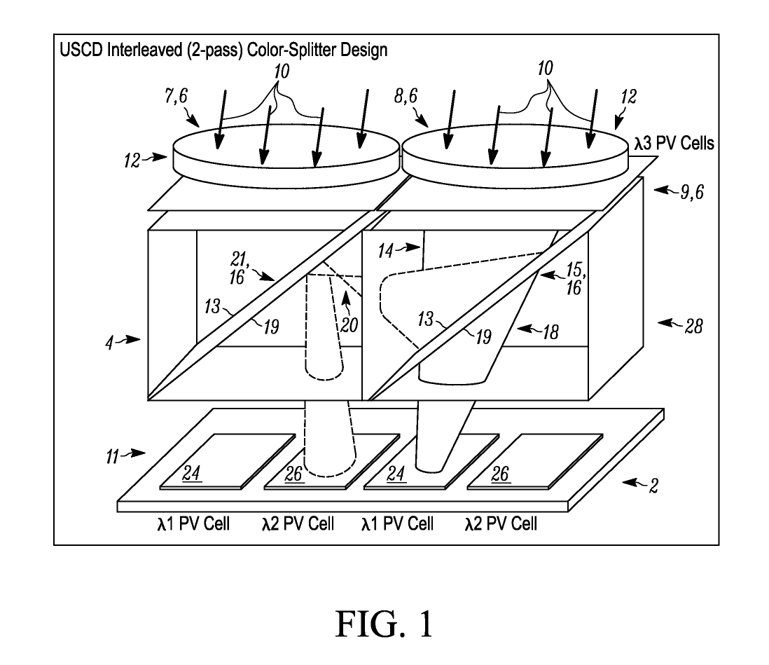

Referring to FIG. 1, a schematic, perspective view is provided showing components of an exemplary solar energy device 2 allowing for both concentration of incoming light as well as separation of such light into light portions within different wavelength ranges that are in turn directed to different types of PV cells, respectively, in accordance with at least one embodiment of the present invention. As shown, the solar energy device 2 includes a solar concentration section 4 that includes multiple solar concentrators 6, a first 8 of which is shown completely, and second 7 and third 9 of which are shown only partly. Additionally, the solar energy device 2 also includes a photovoltaic (PV) cell section 11 that includes multiple PV cells arranged in a coplanar manner, along a side of the solar concentration section 4 that is generally opposite to a side at which incoming light is incident upon that section and upon the overall solar energy device 2.

As illustrated schematically by arrows 10, direct sunlight enters the solar concentrators 6 by way of respective refractive elements 12 (e.g., lenses such as aspheric lenses) having different radii of curvature in orthogonal dimensions so as to modify the acceptance angles from sunlight. Thus, the refractive elements 12 cause the incoming direct sunlight to be refracted such that it would tend to come to a focus at locations after passing through the refractive elements. An additional technique of decentering or using prism microstructure in the refractive elements 12 makes it possible for those elements to form focal points (foci) laterally shifted from their optic axes. Thus, a light ray bundle 14 exiting the refractive element 12 of the solar concentrator 8 in particular is illustrated as taking on a shifted conic appearance.

Prior to coming to foci after exiting the refractive elements 12 within the solar concentrators 6, the light ray bundles are incident upon first sides 13 of tilted, non-planar dichroic mirrors/beamsplitters (hereinafter referred to as dichroic beamsplitters) 16 of the respective solar concentrators. Two of the dichroic beamsplitters 16 are shown in particular, namely a dichroic beamsplitter 15 corresponding to the solar concentrator 8 and a dichroic beamsplitter 21 corresponding to the solar concentrator 7 are shown in particular (the dichroic beam splitter of the solar concentrator 9 is not shown). In particular with respect to the solar concentrator 8, the dichroic beamsplitter 15 is shown to be tilted so as to be neither parallel nor perpendicular with respect to a central axis of the light ray bundle 14 exiting the refractive element 12 of that solar concentrator. In general, the dichroic beamsplitters 16 are all tilted so as to be oriented substantially along planes that are parallel to one another. However, such consistent tilt need not be the case in alternate embodiments.

Each of the dichroic beamsplitters 16 of the solar concentrators 6 includes a thin-film coating commonly known as a “hot mirror”, such that the each of the dichroic beamsplitters serves to transmit a first portion of the light of the respective ray bundle incident thereon through the respective beamsplitter, and also serves to reflect a second portion of the light of that respective ray bundle. Thus, as illustrated in particular with respect to the light ray bundle 14 within the solar concentrator 8, a first (transmitted) portion 18 of the light incident upon the first side 13 of the dichroic beam splitter 15 of that solar concentrator continues along its original straight path. However, a second portion 20 of the light incident upon the first side 13 of the dichroic beam splitter 15 of the solar concentrator 8 is reflected by that dichroic beam splitter so as to proceed in a direction that is substantially orthogonal to the direction of the first portion 18.

The second (reflected) portion of the light incident upon any given one of the dichroic beam splitters 16 of any given one of the solar concentrators 6, upon being reflected off of the first side 13 of the respective beamsplitter, is directed toward the dichroic beam splitter of an adjacent one of the solar concentrators. For example, as particularly shown in FIG. 1, the second portion 20 of the light ray bundle 14 incident upon the dichroic beam splitter 15 of the solar concentrator 8 is reflected toward the dichroic beam splitter 21 of the solar concentrator 7.

In particular, the second portions of the light that are reflected in this manner by the dichroic beam splitters 16 are then incident upon second sides 19 of the dichroic beam splitters 16 of the adjacent solar concentrators, the second sides being opposite to the respective first sides 13 of those dichroic beam splitters that receive the incoming light from the refractive elements 12. Further for example, the second portion 20 reflected by the first side 13 of the dichroic beamsplitter 15 of the solar concentrator 8 is incident upon the second side 19 of the dichroic beam splitter 21, opposite the first side 13 of that dichroic beam splitter, which would receive a light ray bundle (not shown) incoming from the refractive element 12 of the solar concentrator 7.

The second sides 19 of the dichroic beam splitters 16 are reflective such that the second portions of light arriving at those second sides are reflected rather than transmitted through those dichroic beam splitters. More particularly, due to the tilted orientation of the dichroic beam splitters 16 (and particularly the second sides 19 of those beamsplitters), the second portions of light arriving at those second sides 19 are reflected so as to proceed in directions substantially,parallel to the directions of the light transmitted through the dichroic beam splitters. For example, again with respect to the second portion 20 reflected by the dichroic beamsplitter 15 of the solar concentrator 8, that light upon being incident upon the second side 19 of the dichroic beam splitter 21 is in turn reflected by that second side so as to proceed in a direction substantially parallel to the light transmitted through the dichroic beamsplitter 15.

Both the light portions transmitted through the dichroic beam splitters 16 and the light portions reflected off of the second sides 19 of the dichroic beam splitters, being oriented in the same direction, proceed in turn toward PV cells arranged in a coplanar manner upon the PV cell section 11. As shown in FIG. 1, the PV cells of the PV cell section 11 in particular include first PV cells 24 of a first type alternating with second PV cells 26 of a second type. A respective pair of one of each of the first PV cells 24 and the second PV cells 26 is associated with each respective one of the solar concentrators 6.

The respective first PV cell 24 associated with each respective solar concentrator 6 is situated so as to receive the light transmitted through the dichroic beamsplitter 16 of that solar concentrator, while the respective second PV cell 26 associated with each respective solar concentrator is situated so as to receive the light reflected off of the first side 13 of the dichroic beamsplitter of that solar concentrator and then subsequently additionally reflected off of the second side 19 of the dichroic beamsplitter of the corresponding adjacent solar concentrator. Thus, as shown in FIG. 1, the first portion 18 of the light ray bundle 14 transmitted through the dichroic beamsplitter 15 of the solar concentrator 8 is received by the respective first PV cell 24 associated with that solar concentrator. Additionally, the second portion 20 of the light ray bundle 14, which is reflected off of both the first side 13 of the dichroic beam splitter 15 as well as reflected off of the second side 19 of the dichroic beamsplitter 21 of the solar concentrator 7, is in turn received by the respective second PV cell 26 associated with the solar concentrator 8. Sidewall reflectors which may operate under TIR are incorporated in two dimensions to aid in the confinement of light. Tapered trapezoidal interfaces surround the exit pupil of the system to guide the light onto each PV cell at angles close to normal of the cell interface to reduce the severity of surface reflections.

By virtue of the dichroic beam splitters 16 as well as the dual sets of the PV cells 24, 26, the present solar energy device 2 is capable of separating incoming light received from the refractive elements 12 into light portions encompassing different ranges of wavelengths, and subsequently converting those different light portions into electricity using PV cells that are particularly suited for converting light within those different wavelength ranges. More particularly in the present embodiment, the light transmitted through the dichroic beam splitters 16 (e.g., the first portion 18) is at visible wavelengths, while the light reflected by the dichroic beam splitters (e.g., the second portion 20) is light having near-infrared and infrared spectral components and, correspondingly, the first PV cells 24 and second PV cells 26 are respectively suited for processing light energy within the visible and near-infrared/infrared wavelength ranges, respectively.

In short, visible light entering each solar concentrator 6 is transmitted through the dichroic beamsplitter 16 of that concentrator so as to continue along a particular path of incidence (a “z-like path”) toward an optimized visible light PV cell. At the same time, near-infrared/infrared light entering each solar concentrator 6 sees the dichroic beamsplitter 16 of that solar concentrator and has its path redirected towards the reverse side of an identical dichroic mirror existing at an adjacent concentrator. A second reflection causes this portion of the incoming ray bundle to travel in another “z-like” path and propagate in the original direction, but laterally shifted. This band travels through the same series of sidewall reflectors and exits the system onto an optimized near-infrared/infrared PV cell differing from that which receives the transmitted light. Therefore, each solar concentrator collects incident light from a large aperture and field range and condenses the ray paths onto multiple high efficiency photovoltaic (PV) cells to convert the radiation into electricity. Notwithstanding the material bandgaps associated with the different PV cells, by dividing up the incoming light into different portions and directing those portions to different respective PV cells, increased photovoltaic response and highly efficient conversion of the light into electricity can be achieved.

From FIG. 1, several other details about the performance of the solar energy device 2 are also evident. In particular, it will be observed from FIG. 1 that, in the present embodiment, the light ray bundles (e.g., the light ray bundle 14) exiting the refractive elements 12 are configured to have focal lengths such that the foci of the light ray bundles are beyond the plane within which lie the PV cells 24, 26. Thus, the light transmitted through the dichroic beamsplitter 18 never converges upon its foci. In contrast, the light reflected off of the first sides 13 of the dichroic beam splitters 16 (e.g., the second portion 20) does attain and pass through its foci prior to arriving at the second sides 19 of the dichroic beam splitters. Consequently, while the light arriving at the first PV cells 24 is convergent, the light arriving at the second PV cells 26 is divergent. In other words, the initial refractive elements 12 have focal lengths that are longer than the transmission paths, but shorter than the reflection paths, so as to incorporate a degree of defocus. At the same time, in the present embodiment, the dichroic beamsplitters/mirrors are given optical power to minimize divergence.

Additionally, while the dichroic beamsplitters 16 arc described above as being parts of particular ones of the solar concentrators 8, it will be understood that (given the above-described manner of operation) the second sides 19 of the respective dichroic beamsplitters 16 that serve to reflect the light reflected off of the first sides 13 of the adjacent dichroic beamsplitters can equally be said to form parts of those respective adjacent dichroic beamsplitters. It should also be noted that, in at least some embodiments, the solar concentrators 6 include a series of reflective sidewalls 28 in both directions orthogonal to the traveling light, which are incorporated to fold wide angles back towards the optic axis of the system, channeling the fields towards the PV cells. These reflectors may be mirror-based or operate under TIR.

Further, although the embodiment of FIG. 1 serves to separate incoming light into portions that contain visible and near-infrared/infrared light, in other embodiments the incoming light can be separated into light of two or more other wavelength ranges. Also although the above description characterizes the reflections occurring off of the dichroic beamsplitters 16 as resulting in light transmission that is substantially orthogonal to the direction of the light prior to its incidence upon those beamsplitters, the particular directions of light transmission will vary for any given ray and the orthogonality need not be exact, but rather these aspects can vary depending upon the embodiment. For example, while the dichroic beamsplitters are shown in FIG. 1 as being generally oriented at 45 degree angles relative to the light incoming from the refractive elements, the beamsplitters can also be oriented at other angles relative to the incoming light, provided that the different beamsplitters are all oriented at the same or substantially the same angle such that the first and second reflections off of the first and second beamsplitters of each pair of beamsplitters involve the same or substantially the same reflective angle (that is, so that the first and second reflections effectively form a pair of alternate interior angles). At the same time, regardless of the particular configuration of the components, it is typically desirable that the different portions of light intended for receipt by different types of PV cells be directed, in the end, towards the same plane upon which the different PV cells are arranged. Locating all of the PV cells (or at least large groupings of PV cells) along the same plane allows for reduced cost in manufacturing as well as reduces the size of the overall solar energy device.

Additionally, although the above description characterizes the solar energy device 2 as having an indeterminate number of adjacent solar concentrators 6 such that each dichroic beamsplitter 16 of each solar concentrator can reflect light towards an adjacent dichroic beamsplitter of an adjacent solar concentrator, the solar energy device will be finite in extent in practice and consequently the dichroic beamsplitters 16 at the ends/edges of the solar energy device can operate differently than the other dichroic beamsplitters that are in between the ends/edges. More particularly, in at least some embodiments, the dichroic beamsplitters at one or both of the ends/edges can be configured to perform only a transmittive or reflective function but not both, can be configured to transmit and reflect incoming light from a refractive element without reflecting light incoming from another beamsplitter, or can be configured to merely reflect light that has already been reflected by another dichroic beamsplitter (indeed, in some cases, dichroic beamsplitters need not be employed at the ends/edges). It should be also noted that, just as the PV cells 24, 26 can be formed as the single PV cell section I 1, the entire solar concentrator section 12 can be constructed as a volume from common index material. Also, in at least some embodiments, solar concentrators assembled from materials with varying index and dispersion characteristics or air gaps within the optical track are possible.

Further, although the above-described solar energy device 2 employs the multiple adjacent dichroic beamsplitters 16 that are arranged side by side and serve to separate incoming light into two portions (namely, the first, transmitted portion and the second, doubly-reflected, portion), it will be understood that the above device can be expanded in an iterative manner so as to allow for the separation of incoming light into three or more portions as well. For example, if a second row of dichroic beamsplitters was placed between the PV cell section and the currently-described row of dichroic beamsplitters, the second row of dichroic beamsplitters could be employed to separate the second, doubly-reflected portions of light into further transmitted and quadruply-reflected portions of light. In such case, the PV cell section could be formed to include three rather than two sets of PV cells, where the third set of PV cells was optimized to receive the light of the quadruply-reflected portions. Thus, the above-described solar energy device 2 can be arbitrarily modified to separate incoming light into any arbitrary number of portions of different wavelengths for receipt by any arbitrary number of different types of PV cells.

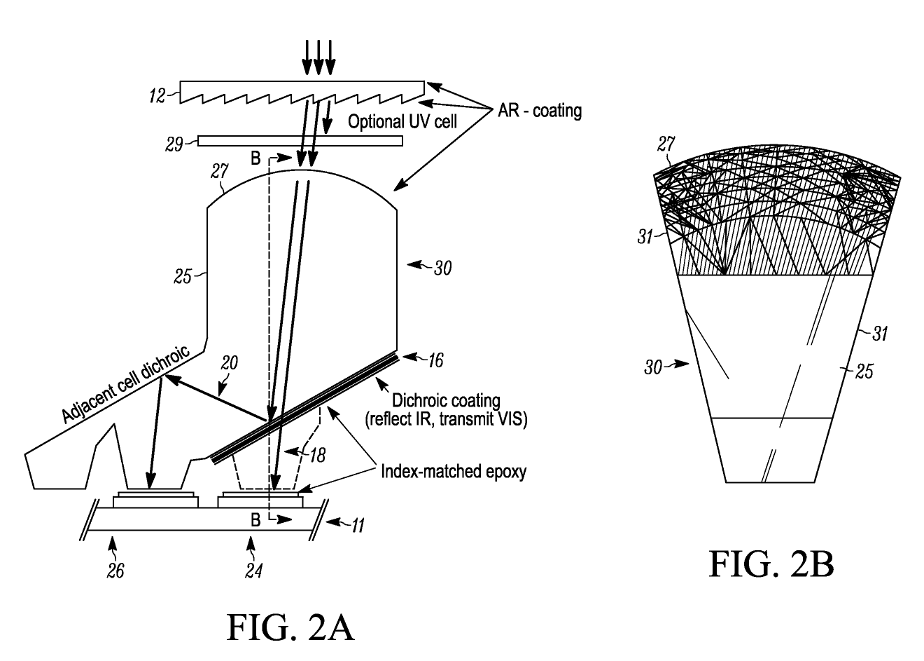

Turning to FIGS. 2A-B and 3A-3C, additional views are provided of exemplary components 30 that can be implemented in the solar energy device 2 represented by FIG. 1 (or devices similar thereto), which show in more detail (and not merely schematically) a particular exemplary configuration of those components. FIG. 2A in particular shows a side elevation view of one of the components 30, which could be implemented as one of the solar concentrators 6 and the associated PV cells of the PV cell section 11. As shown, the component 30 includes a refractive element 12, a light-transmitting structure 25 (which can be made of UV-transparent acrylic plastic), and a dichroic beamsplitter 16, as well as an optional UV cell 29 positioned between the refractive element and the primary light-transmission structure, which can be considered to constitute a solar concentration portion of the component. In this regard, a single micro-optic structure thus incorporates both a lens and a dichroic beamsplitter (which can also be referred to as a dichroic mirror, reflector, or filter).

As shown, the light-transmitting structure 25 in the present embodiment has a “dog-leg” type shape (when viewed from the side as shown in FIG. 2A) that particularly includes a curved edge 27 by which light from the refractive element 12 enters the light-transmitting structure, and also a diagonally extending surface at which the dichroic beamsplitter 16 is mounted or formed (in some cases, the beamsplitter is a separate mirror structure, while in other cases the beamsplitter is formed through the use of a dichroic coating such that the element 12, structure 25 and beamsplitter 16 all can be formed by way of a single-piece fabrication technique). The curved edge 27, and in some cases both the curved edge as well as one or both of the refractive element 12 and the UV cell 29, can be coated with an anti-refractive coating. Although not shown, it will be understood that the second side of the dichroic beamsplitter of an adjacent solar concentrator would need to be present in order to provide the reflection of the second portion 20 of the light as illustrated. Additionally as shown, the component 30 further includes an associated pair of one of the first cells 24 and one of the second cells 26.

Further, FIG. 2B shows a cross-sectional view of the component 30, and in particular shows sidewall reflectors 31 of that component, which in the present embodiment are planar and tapered (or in some sense conic) so that the component 30 becomes thinner as one proceeds more closely toward the PV cells. The sidewall reflectors 31 can operate under TIR and aid in the confinement of light, particularly by limiting the angular extent of output light rays (that is, light rays exiting towards the PV cells). In one embodiment, the dimensions of the component 30 shown in FIG. 2B are approximately 5 mm in width along the curved edge 27 upon which incoming light is incident, approximately 1.9 mm in width along the edge opposite the curved edge at which light exits the structure for receipt by PV cells, and approximately 6.17 mm in height (the distance between those two other edges). The length of the component (which dimension is not shown in FIG. 2B but is shown in FIG. 2A) can be also 5 mm along the curved edge 27, but is greater (approximately double that figure, or 10 mm) along the opposite edge at which light exits for receipt by PV cells, due to the dog-leg shape of the component 30.

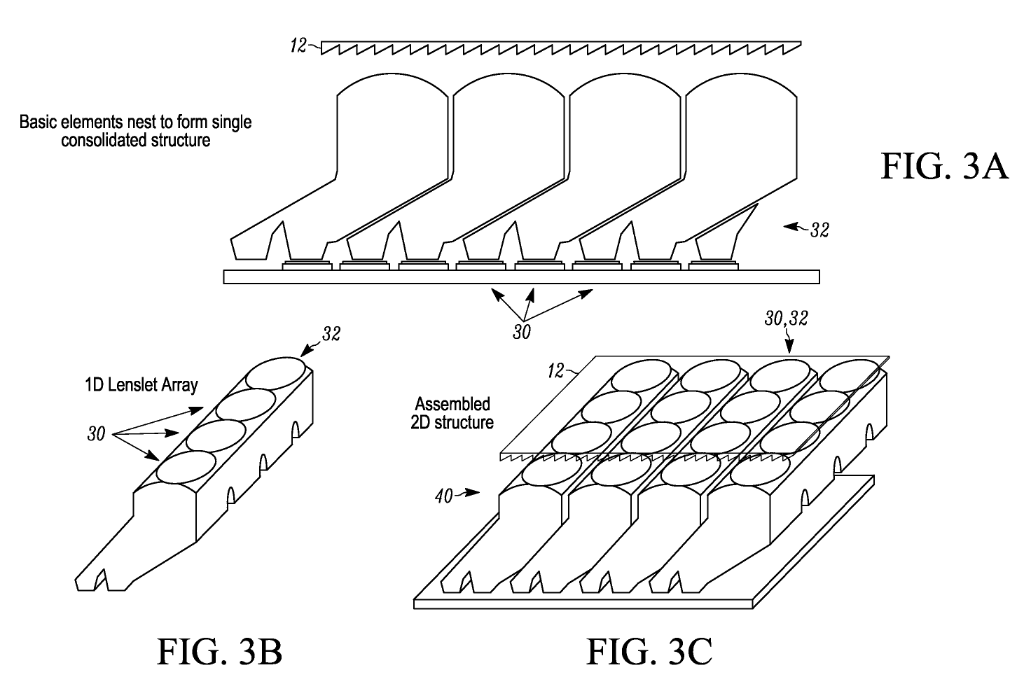

As for FIGS. 3A-3B, these figures illustrate how several of the components 30 shown in FIGS. 2A-B can be positioned adjacent to one another to form a line 32 (one-dimensional array) of solar concentrators and associated PV cells. FIG. 3A in particular shows a side elevation view of such a structure, while FIG. 3B shows a perspective view. As for FIG. 3C, that figure further illustrates how several of the lines 32 can in turn be positioned adjacent to one another to form a matrix 40 (two-dimensional array) of solar concentrators and associated PV cells. In the embodiments shown in FIGS. 3A-3C, the optional UV cell 29 described above is not present. The matrix 40 can be considered a thin sheet geometry that can be implemented with reduced optical volumes. For example, in one exemplary embodiment a square matrix having an area of approximately 25 square centimeters (approximately 5 centimeters per side) on which light would be incident would only need to have a depth of 0.62 centimeters (in terms of the distance between the edges of the refractive elements at which light is incident and the opposite surface along which are located the PV cells), such that the total volume of the matrix structure would be only 17 cubic centimeters (F/1.4 Fresnel: 175 cubic centimeters).

Thus, the design shown in FIGS. 2A-3C is well suited for creating a variety of different solar energy devices of varying size and shape. An exemplary process of manufacturing a given solar energy device can involve the steps of (1) providing a micro-optic diamond turned master for manufacturing components such as the component 30 of FIG. 2A (having among other things an aspheric lens and Zernike-based reflector), (2) replicating a process by which such components 30 are manufactured so as to generate a linear or one-dimensional array of such components (this can involve glass or plastic molding technologies), (3) applying anti-refractive coating (and, in embodiments where the dichroic beamsplitters are formed by way of dichroic coatings) and dichroic coatings as appropriate (all other reflections being TIR), (4) forming 2-dimensional arrays of the components 30 (this can be achieved in part by assembling components using, for example, index-matching epoxy), and (5) mounting the 2-dimensional arrays on top of co-extensive 2-dimensional arrays of pairs of the PV cells, resulting in a completed 2-dimensional solar energy device.

Thus, by arranging the solar concentrators into linear arrays as shown, a large area solar cell can be constructed by assembling the linear arrays into a two-dimensional panel. The concentrator geometry allows all the PV detector elements to be interleaved and mounted on a single circuit board. Each linear array can be injection molded and then coated, making the unit costs low. Where dichroic beamsplitters are implemented simply by spraying dichroic coating onto the acrylic light-transmitting structures 25, the dichroic coating in particular can be sprayed all around those entire structures 25 except for the portions corresponding to the curved edges 27 described above at which light is incident upon those structures 25 and the opposite edges at which the light exits those structures 25 (including possibly side surfaces immediately adjoining those edges at which neighboring ones of the components 30 may be in contact). Although FIG. 3A suggests that linear arrays are first created by combining components 30 in a lengthwise manner such that the surfaces along which are positioned the dichroic beamsplitters of the different components are in contact with one another, linear arrays can also first be achieved in the opposite, side-by-side manner, such that all of the surfaces along which the dichroic beamsplitters are positioned remain exposed until such time as multiple linear arrays are combined with one another to form the two-dimensional matrix.

By placing different types of PV cells (that is, PV cells suited for receiving light in different wavelength ranges) in the same plane, thermal management, fill factor and packaging are all improved. Specifically with respect to thermal management, this is particularly enhanced by the collocation of the PV cells in the same plane, since this allows for a common heatsink to be used. Additionally, the design is well suited for manufacture using injection molding of optically transparent plastic, and for simplified packaging. Further, because different portions of light (within the different wavelength ranges) can be provided to different PV cells suited for those different portions of light even while those PV cells are collocated on the same plane, with some of the light being directed to PV cells located to the sides of the axes along which incident light first enters the system and is directed toward the dichroic mirrors (i.e., off-axis illumination), the usable space behind the refractive elements/lenses is maximized. It should be noted that, in some embodiments, off-axis illumination options can also include the use of a prism array, tilting of the system or system components, or decentered lens elements.

It should be noted that, in designing devices such as those of FIGS. 1-3C, sunlight acceptance angles and concentration ratio are important parameters when optimizing the surface curvature of the refractive (entrance) lenses and dichroic mirrors. A non-sequential ray tracing platform has been created in Zemax (e.g., using Zemax Non-Sequentials software as available from Zemax Development Corporation of Bellevue, Wash.) and can be easily run to generate a design for a given specification and performance set. In at least some embodiments as described above, the lenses are designed to have intermediate focal distances between ray paths so as to defocus and minimize hot spots. Also in at least some embodiments, rays exiting the solar concentration sections (that is, particularly after transmission through or the reflections off of the dichroic beamsplitters) exit at less than plus or minus 45 degree angles using the tapered sidewalls so as to improve coupling to the PV cells.

Additionally, in at least some embodiments, the dichroic beamsplitters are designed to have two sides that are each reflective with respect to at least some light, and can be designed using circular Zernike Polynomials. The dichroic beamsplitters typically have two different reflective regions, a first where light incoming from a refractive element is partly reflected towards an adjacent dichroic beamsplitter (as well as partly transmitted through the dichroic beamsplitter), and a second where light that has already been reflected off of another dichroic beamsplitter is again reflected, with the two reflective regions being located on opposite sides of the dichroic beamsplitter. Thus, the dichroic beamsplitters in such embodiments are particularly designed to accommodate both front and back surface illumination (i.e., illumination on both sides of the beamsplitter) as well as optimized for the different types of reflections occurring on the different sides of the beamsplitters. Unique curvature can further aid in concentration in some embodiments. Once a design is finalized, the component can be exported to a mechanical design software such as SolidWorks (e.g., as available from Dassault Systemes S.A. of Vélizy-Villacoublay, France) or computer-aided design (CAD) for manufacturing preparations.

From the above description, it should be apparent that at least some embodiments of the present invention can be considered a solar energy system employing one or more passive wavelength-banded solar concentrators. In other embodiments, the solar concentrators however can also employ active realignment such that the solar concentrators can satisfactorily receive sunlight incident from a variety of directions (e.g., where realignment occurs over time to adjust to variations in the angle of incidence of the sunlight). Also, from the above description, it should be apparent that at least some embodiments of the present invention can be considered a solar energy system employing a bulk micro-optic solar concentrator.

In at least some embodiments, the present invention uses a solid plastic construction, for a rugged and inexpensive device. A single refractive element is used at the entrance of the concentrator. This element can be decentered or an additional microprism/grating structure can be incorporated to cause the element to form a focus off axis. Reflective baffles placed orthogonal to the optic axis can be used to form a cone concentrator to fold wide angle fields back towards the detecting PV cell. Using a series of baffles allows concentration over a significantly wider field of entrance angles without incorporating active tracking of the sun. This type of solar concentrator is well suited for small scale power generation for portable device charging or the powering of other small electronics such as cellphones, cameras, laptop computers and radios.

In addition to being used in solar collectors for generating electrical (or other power), potential applications such as the powering of remote cameras/sensors are also envisioned for embodiments of the present invention. The number of concentrators and the aspect ratio can easily be scaled to provide greater collection area and more power generation. Applications in local power generation for temporary emergency response locations or surveillance installations can therefore be foreseen.

It is specifically intended that the present invention not be limited to the embodiments and illustrations contained herein, but include modified forms of those embodiments including portions of the embodiments and combinations of elements of different embodiments as come within the scope of the following claims.

We claim:

1. A system for capturing solar energy, the system comprising:
a plurality of lenses arranged side-by-side with respect to one another, each of which is capable of receiving and focusing a respective amount of sunlight;
a plurality of dichroic mirrors that respectively extend diagonally away from respective ones of the lenses, and that are positioned so that the respective amounts of sunlight focused by the respective lenses are respectively incident upon the respective dichroic mirrors; and
a plurality of pairs of first and second photovoltaic cells arranged substantially side-by-side with one another along a substantially planar surface, wherein each of the dichroic mirrors is positioned substantially in between a respective one of the lenses and at least the first photovoltaic cell of a respective one of the pairs of photovoltaic cells,
wherein the first photovoltaic cell of each of the respective pairs receives a respective first portion of the respective amount of sunlight focused by the respective one of the lenses that is transmitted through the respective dichroic mirror, and
wherein the second photovoltaic cell of each of the respective pairs receives a respective second portion of the respective amount of sunlight focused by the respective one of the lenses that is reflected by the respective dichroic mirror and subsequently reflected again by a respective neighboring one of the plurality of dichroic mirrors prior to arriving at the respective second photovoltaic cell.

2. The system of claim 1, wherein the first portions of the amounts of sunlight are within a first wavelength range, and the second portions of the amounts of sunlight are within a second wavelength range.

3. The system of claim 1, wherein the respective dichroic mirrors have first sides and second sides, and wherein each respective second portion arrives at the respective second photovoltaic cell after being first reflected by one of the first sides of the dichroic mirrors and then subsequently reflected again by one of the second sides of the dichroic mirrors.

4. The system of claim 1, wherein each of the plurality of dichroic mirrors extends along a respective plane, and wherein all of the planes are substantially parallel with one another.

5. The system of claim 1, wherein all of the planes are oriented so as to form a substantially 45 degree angle relative to a z-axis direction that is perpendicular to a plane along which are arranged all or substantially all of the photovoltaic cells.

6. The system of claim 1, wherein the first portions of the amounts of sunlight that are transmitted through the respective dichroic mirrors do not reach their respective focal points prior to reaching the respective dichroic mirrors.

7. The system of claim 1, wherein the respective lenses include respective internal reflection condensers.

8. The system of claim 1, further comprising:
(a) a microprism cover plate, wherein at least one of the lenses is positioned between the microprism cover plate and the respective dichroic mirrors; and
(b) at least one ultraviolet photovoltaic cell positioned between the microprism cover plate and at least one of the lenses.

9. The system of claim 1, wherein the system is formed at least in part by combining a plurality of substantially identical components into a linear array, each of which includes a respective one of the lenses, a respective one of the dichroic mirrors, and a respective one of the pairs of photovoltaic cells.

10. A system for capturing solar energy comprising the system of claim 9 and a plurality of additional systems each also having respective pluralities of lenses, dichroic mirrors, and pairs of photovoltaic cells, so as to comprise overall a two-dimensional array of lenses, dichroic mirrors and photovoltaic cells.

11. A method for capturing solar energy, the method comprising:
receiving light at a plurality of lenses;
communicating the light from respective ones of the plurality of lenses toward respective ones of a plurality of dichroic mirrors;
transmitting respective first portions of the light through the respective ones of the dichroic mirrors toward respective first photovoltaic cells;
reflecting respective second portions of the light off of the respective ones of the dichroic mirrors toward respective adjacent ones of the dichroic mirrors, wherein the first portions are within a first wavelength range and the second portions are within a second wavelength range; and
reflecting the respective second portions of the light off of the respective adjacent ones of the dichroic mirrors toward respective second photovoltaic cells, whereby the first and second portions of the light are converted into electrical power by way of the first and second photovoltaic cells, respectively.

12. The method of claim 11, wherein the first and second photovoltaic cells are positioned side-by-side in an alternating manner.

13. The method of claim 12, wherein the first and second photovoltaic cells are located substantially along a single plane.

14. The method of claim 11, wherein the first and second photovoltaic cells together form a photovoltaic cell section, and the plurality of lenses and plurality of dichroic mirrors together form a solar concentrator section.

15. The method of claim 14, wherein the solar concentrator section includes a plurality of sidewall reflectors to enhance internal reflection within the solar concentration so as to more effectively direct the light toward the dichroic mirrors.

16. The method of claim 11, wherein the lenses are refractive elements that serve to focus the light toward a plurality of focal points, and wherein an ultraviolet cell is positioned between the lenses and the dichroic mirrors.

17. The method of claim 11, wherein the method further comprises assembling the pluralities of lenses, dichroic mirrors and pairs of photovoltaic cells into a linear array.

18. The method of claim 17, wherein the method further comprises assembling the pluralities of lenses, dichroic mirrors and pairs of photovoltaic cells into a two-dimensional array.

19. A method of capturing light energy comprising:
receiving a plurality of amounts of light at a plurality of dichroic mirrors, respectively;
transmitting respective first portions of the respective amounts of light through respective ones of the dichroic mirrors for receipt by a plurality of first photovoltaic cells, respectively; and
doubly reflecting respective second portions of the respective amounts of light, first off of the respective ones of the dichroic mirrors and then additionally off of respective adjacent ones of the dichroic mirrors for receipt by a plurality of second photovoltaic cells, respectively, the first photovoltaic cells and the second photovoltaic cells being arranged in an alternating manner with respect to one another.

20. The method of claim 19, wherein at least some of the plurality of dichroic mirrors serve both as some of the ones of the dichroic mirrors off of which some of the respective ones of the second portions of the amounts of light are first reflected, and also as some of the adjacent ones of the dichroic mirrors off of which some of the second portions of the amounts of light are additionally reflected.
